(19) United States
(12) Patent Application Publication
(10) Pub. No.: US 2026/0128195 A1
(43) Pub. Date: May 7, 2026

(54) Tapered Connectors for Superconductor Circuits

(71) Applicant: PsiQuantum Corp., Palo Alto, CA (US)

(72) Inventors: Brad A.J. Moores, Boulder, CA (US); Faraz Najafi, San Francisco, CA (US)

(21) Appl. No.: 18/941,889

(22) Filed: Nov. 8, 2024

Related U.S. Application Data
(63) Continuation of application No. PCT/US2023/021568, filed on May 9, 2023.
(60) Provisional application No. 63/340,392, filed on May 10, 2022.

(51) Int. Cl. H01B 12/02; H10N 60/83

(52) U.S. Cl. CPC H01B 12/02; H10N 60/83

(57) ABSTRACT

The various embodiments described herein include methods, devices, and circuits for reducing or minimizing current crowding effects in manufactured superconductors. In some embodiments, a superconducting circuit includes: (i) a first component; (ii) a second component; (iii) a third component; and (iv) a superconducting connector electrically connecting the first component, the second component, and the third component, the connector including a first section that splits at a splitting end into a second section and a third section. The first section connecting to the first component at a first end and widening in accordance with an electrical current streamline prior to the splitting end.

### RELATED APPLICATIONS

This application is a continuation of PCT Patent Application Serial No. PCT/US2023/021568, filed May 9, 2023, which claims the benefit of and priority to U.S. Provisional Patent Application No. 63/340,392, filed May 10, 2022, each of which is incorporated by reference herein in its entirety.

### TECHNICAL FIELD

This relates generally to superconducting circuits, including but not limited to, tapered connectors for superconducting circuits.

### BACKGROUND

Superconductors are materials capable of operating in a superconducting state with zero electrical resistance under particular conditions. One parameter for operating in a superconducting state is current density. If current density exceeds a superconducting density threshold the superconductor will operate in a non-superconducting state. Geometric shapes such as corners may lead to current crowding effects that result in the current density exceeding the superconducting density threshold at some locations.

### SUMMARY

Geometric shapes, such as bends, corners, and splits, in a superconducting circuit can result in current crowding effects if not constructed appropriately. The current crowding effects can cause the superconducting circuit to operate a non-superconducting state, which may result in operational failures and erroneous results. A mathematically-optimal geometry can be calculated for some standard shapes, such as 90-degree turn or a 180-degree turn. However, in some circumstances these standard shapes are insufficient to construct a larger superconducting circuit or system. For example, sizing and layout requirements of the superconducting circuit or system may require a superconducting connector to split; or require the superconducting connector to have a non-standard turn angle.

In accordance with some embodiments, an iterative process is used for designing a superconducting connector having a geometric shape such as a bend, corner, or split. For example, an initial boundary is selected for the connector (e.g., having a constant width). Then current is simulated through the connector to identify any current crowding locations (e.g., locations where the current density exceeds a superconducting density threshold). To continue the example, a current streamline from the simulation is used to generate an updated boundary for the connector (e.g., having an increased width in proximity to the bend, corner, or split). In accordance with some embodiments, the simulation and selection of an updated boundary is repeated until the simulation results show no current crowding locations.

This iterative process allows for the construction of connectors that have a reduced or minimized area as compared to connectors with only standard shapes. In some circumstances, the reduced area results in more accurate superconducting circuitry that is less susceptible to errors introduced by errant photons being absorbed by the superconducting circuitry and connectors. In addition to making more compact superconducting circuits and systems, this process allows for construction of connectors that are more tolerant to variations introduced by a fabrication process (e.g., lithography).

Accordingly, in one aspect, some embodiments include a superconducting circuit having a first component, a second component, a third component, and a superconducting connector electrically connecting the first component, the second component, and the third component, the connector including a first section that splits at a splitting end into a second section and a third section; where the first section connects to the first component at a first end; where the first section widens (e.g., tapers outward) prior to the splitting end; and where the first section widens in accordance with an electrical current streamline.

In another aspect, some embodiments include a method of generating (e.g., designing) superconducting connectors. The method includes: (i) setting a shape for a superconducting connector having a feature, the shape including a first edge contour for the feature; (ii) identifying one or more hot spots and a plurality of current streamlines in the superconducting connector by simulating current flow through the superconducting connector; (iii) selecting a first streamline of the plurality of streamlines, the first streamline being adjacent to at least one hot spot of the one or more hot spots; and (iv) adjusting the shape for the superconducting connector to have a second edge contour for the feature, the second edge contour shaped in accordance with the first streamline.

Thus, devices and circuits are provided with methods for reducing or minimizing current crowding by use of tapered connectors, thereby increasing the effectiveness, efficiency, and user satisfaction with such circuits and devices. Such circuits, devices, and methods optionally complement or replace conventional devices, circuits, and methods for reducing or minimizing current crowding effects.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIGS. 1A-1B are diagrams illustrating an example connector in accordance with some embodiments.

FIGS. 2A-2D are diagrams illustrating example connectors with splits in accordance with some embodiments.

FIGS. 3A-3C are diagrams illustrating example connectors with splits in accordance with some embodiments.

FIGS. 4A-4C are diagrams illustrating an example connector with a bend in accordance with some embodiments.

FIGS. 5A-5C are diagrams illustrating example connectors with bends in accordance with some embodiments.

FIG. 6 is a flowchart illustrating an example method for generating superconducting connectors in accordance with some embodiments.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

A threshold superconducting current for a superconductor component is dependent on current density within the superconductor component. Current crowding effects at corners or curves lead to increased current density, which in turn leads to a lower threshold superconducting current. Therefore, it is important to shape the superconductor component to reduce or minimize current crowding effects (e.g., through the use of tapered connectors).

Mathematically-optimal tapers can minimize current crowding in superconductor devices. However, mathematically-optimal tapers can be difficult to manufacture in some circumstances, such as with superconductor devices having non-standard geometries and/or width(s) that are less than 1 micron. For example, drift during an e-beam process leads to stepping of a mathematically-optimal curve, which increases current crowding effects. As another example, a lithography process may over-expose or under-expose parts of a steep curve, which also increase current crowding effects. The present disclosure describes superconducting tapers that both prevent current crowding and are manufacturable.

Equations (1)-(3) below are examples of curves that meet certain current crowding reduction criteria (e.g., are mathematically-optimal curves). Equation (1) defines a curve along the x-axis and y-axis for a component with a 90-degree turn.

$$Equation 1 - Curve for 90 - degree Turn$$

$${y}_{90} ( x ) = W \{ 1 + \frac{2}{π} sin {h}^{- 1} [ \frac{1}{sin h [ π / 2 W ) ( x - W ) ]} ] \}$$

In Equation (1) above, W is the width of the component prior to (e.g., outside, but adjacent to) the turn (e.g., a straight portion of the component). Equation (2) defines a curve along the x-axis and y-axis for a component with a 180-degree turn (e.g., a u-shaped turn).

$$Equation 2 - Curve for 180 - degree Turn$$

$${y}_{180} ( x ) = \pm ( 2 W / π ) {cos}^{- 1} [ exp ( π x / 2 W ) / 2 ]$$

In Equation (2) above, W is the width of the component prior to (e.g., outside, but adjacent to) the turn. Equation (3) shows a complex-number function zeta, ζ(c), indicating a curve along the x-axis and y-axis for a tapered component.

$$Equation 3 - Complex - number Function for Tapered Portion$$

$$ζ ( c ) = \frac{i}{π} [ W {tan}^{- 1} ( \frac{\sqrt{c ( α ) - γ}}{\sqrt{γ + 1}} ) + A {tan}^{- 1} ( \frac{\sqrt{γ - 1}}{\sqrt{c ( α ) - γ}} ) ]$$

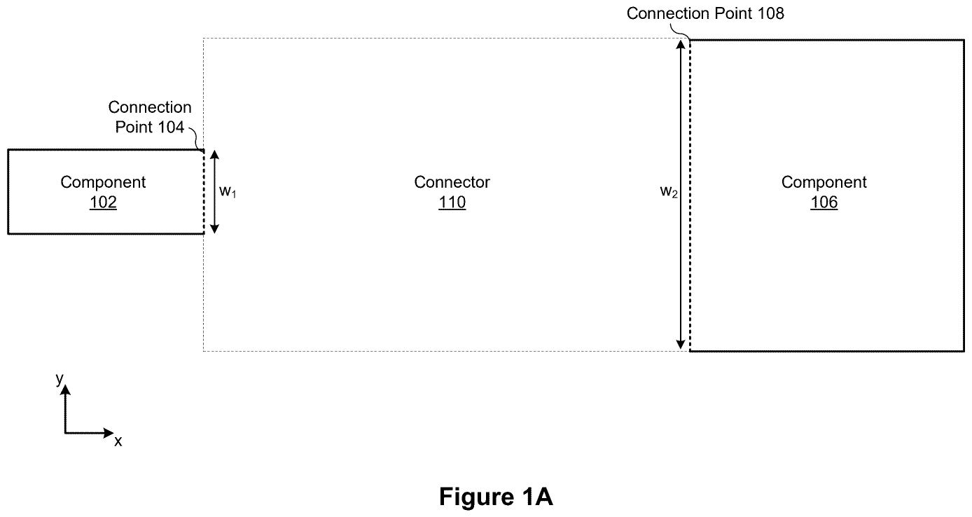

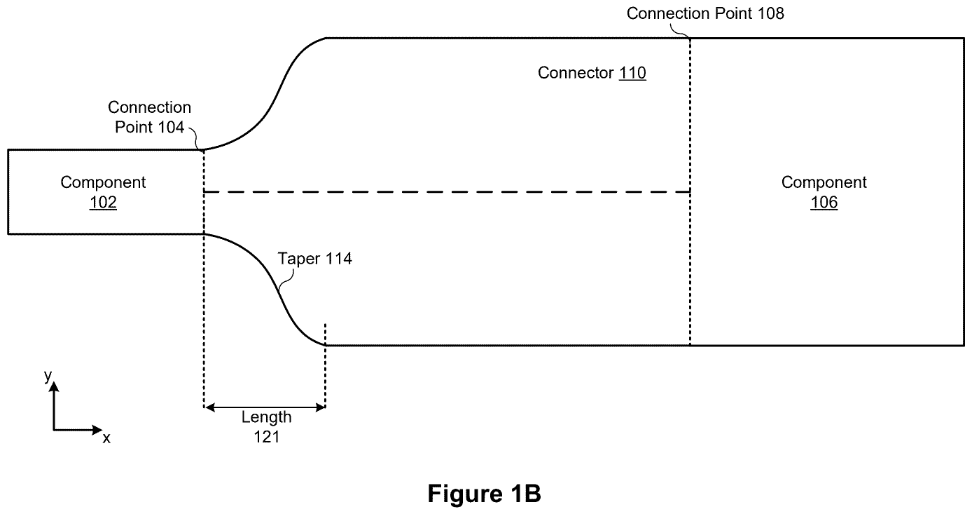

In Equation (3) above, W is the width of the narrow end of the tapered portion (e.g., w₁ in FIG. 1A), A is the width of the wider end of the tapered portion (e.g., w₂ in FIG. 1A), gamma (γ) is defined by Equation (4), and c(α) is defined by Equation (5).

$$Equation 4 - Relationship Between Wide and Narrow Ends$$

$$γ = \frac{( {A}^{2} - {W}^{2} )}{( {A}^{2} - {W}^{2} )}$$

$$Equation 5 - Angle Mapping$$

$$c ( α ) = cos ( α ) + i sin ( α )$$

As the angle α in Equation (5) is varied from 0 to π, the x and y coordinates for a curved boundary of the tapered portion can be obtained via Equations (6) and (7) below.

$$Equation 6 - X - coordinate of Curved Boundary$$

$$x ( α ) = Re ( ζ ( α ) )$$

$$Equation 7 - Y - coordinate of Curved Boundary$$

$$y ( α ) = Im ( ζ ( α ) )$$

As shown in Equations (6) and (7) above, the x-coordinate is obtained from the real portion of the function zeta and the y-coordinate is obtained from the imaginary portion of the function zeta.

FIGS. 1A-1B are diagrams illustrating an example connector in accordance with some embodiments. FIG. 1A shows a component 102 and a component 106 coupled by a connector 110 in accordance with some embodiments. The component 102 has a connection point 104 with a first width, w₁. The component 106 has a connection point 108 with a second width, w₂. As shown in FIG. 1A, w₂ is greater than w₁. In some embodiments, the connector 110 is adapted (e.g., shaped) to reduce current crowding within the connector. In some embodiments, the component 102, the component 106, and the connector 110 are arranged on a same layer of superconducting material. In some embodiments, the component 102, the component 106, and the connector 110 are composed of a same material (e.g., a superconducting material such as NbGe or NbN). In some embodiments, the component 102, the component 106, and the connector 110 are formed via etching of a superconducting film. In some embodiments, one of the components 102 and 106 is a photon detector (e.g., a superconducting nanowire single photon detector (SNSPD)). In some embodiments, one of the components 102 and 106 is a pad or via. In some embodiments, one of the components 102 and 106 is an inductor or resistor.

In various embodiments, the connector 110 has various tapered shapes to reduce or minimize current crowding effects as current flows between the component 102 and the component 106. In some embodiments, if the ratio of w₂ to w₁ is less than a preset factor (e.g., 3, 4, or 5, or more generally a predefined value between 2.5 and 5), the connector 110 has a tapered shape meeting one or more current crowding reduction criteria (e.g., mathematically-optimal tapered shape), such as the tapered shape set forth in Equations (3)-(7) above. In some embodiments, if the ratio of w₂ to w₁ is greater than the preset factor, the connector 110 includes a series of tapers, or a tapered shape that is elongated from a tapered shape meeting one or more current crowding reduction criteria (e.g., mathematically-optimal tapered shape), such as the tapered shape set forth in Equations (3)-(7) above. In some embodiments, each taper is a tapered region of superconducting material having two ends, each end of the tapered region having a distinct width. In some embodiments, the taper(s) of the connector 110 (e.g., the taper 114 shown in FIG. 1B) are shaped so as to reduce current crowding within the connector 110. In some embodiments, the tapers of the connector 110 are adapted (e.g., designed) based on a lithography process used to form the connector. In some embodiments, the connector 110 includes one or more tapered regions and the tapered region(s) have respective first derivatives that are matched at connection point(s) of the tapered regions.

FIG. 1B shows the connector 110 with a taper 114 from the connection point 104 in accordance with some embodiments. As shown in FIG. 1B, the taper 114 is a non-linear taper increasing in width from the width w₁ of the connection point 104 to the width w₂ of the connection point 108 along a length 121. In some embodiments, the tapered shape of the taper 114 is set in accordance with Equations (3)-(7) above. In some embodiments, the tapered shape of the taper 114 is set in accordance with a current streamline for current flowing through the connector 110.

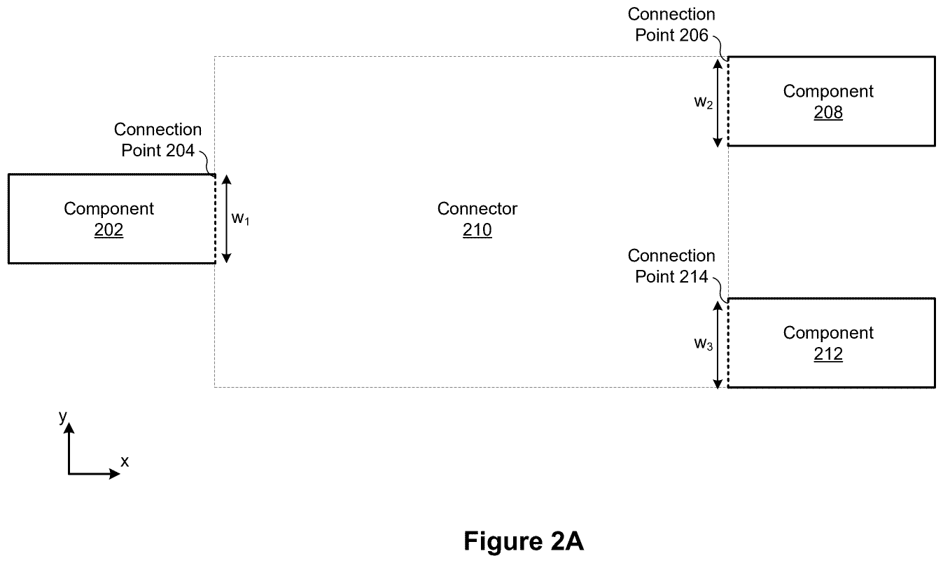

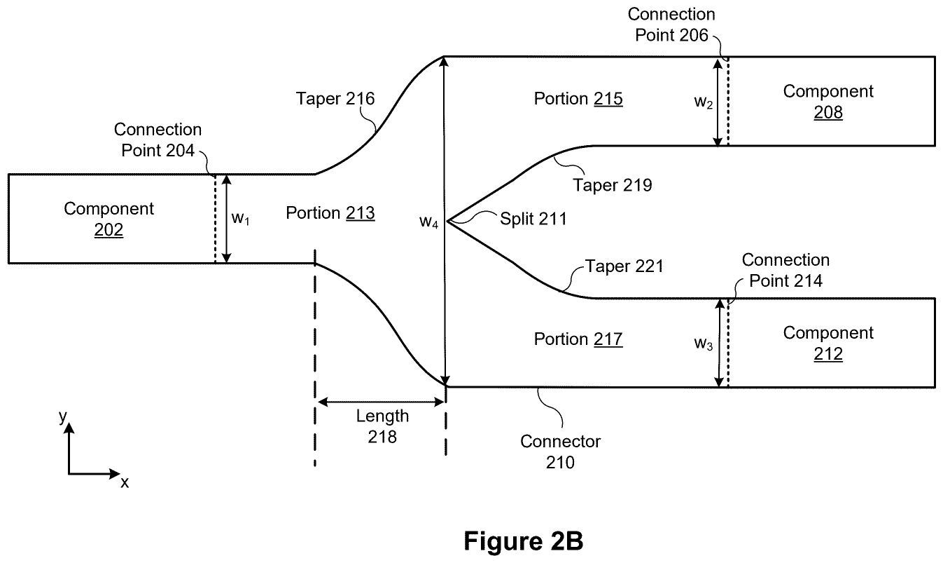

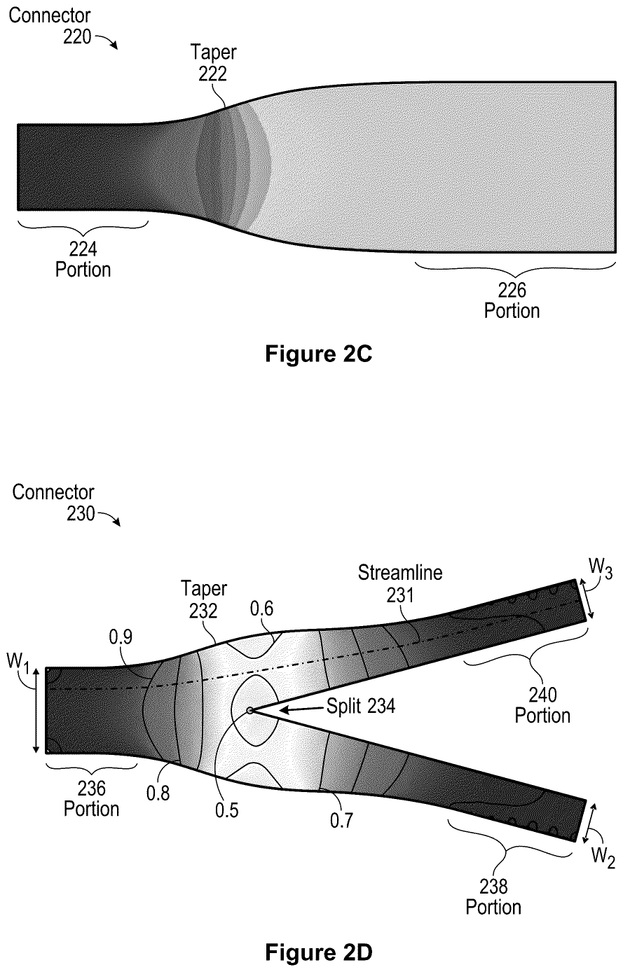

FIGS. 2A-2D are diagrams illustrating example connectors with splits in accordance with some embodiments. FIG. 2A shows components 202, 208, and 212 coupled by a connector 210 in accordance with some embodiments. The component 202 has a connection point 204 with a first width, w₁. The component 208 has a connection point 206 with a second width, w₂, and the component 212 has a connection point 214 with a third width, w₃. In some embodiments, the connection points 204, 206, and 214 have equal widths (w₁, w₂, and w₃ are equal). In some embodiments, the connection points 204, 206, and 214 have differing widths (e.g., w₁ is greater than w₂ and w₃). In some embodiments, the connector 210 is adapted (e.g., shaped) to reduce current crowding within the connector. In some embodiments, the components 202, 208, and 212 and the connector 110 are arranged on a same layer of superconducting material (e.g., a superconducting material such as NbGe or NbN). In some embodiments, the connector 210 is formed via etching of a superconducting film. In some embodiments, the components 202, 208, and 212 are instances of the component 102 or the component 106.

FIG. 2B shows the connector 210 having a portion 213 and a split 211 to a portion 215 and a portion 217 in accordance with some embodiments. The portion 213 from the connection point 204 to the split 211 includes an outward taper 216 (e.g., a widening) from the width w₁ to a width w₄ along a length 218. The portion 215 includes an inward taper 219 (e.g., a narrowing) from the width w₄/2 at the split 211 to the width w₂ at the connection point 206. The portion 217 includes an inward taper 221 from the width w₄/2 at the split 211 to the width w₃ at the connection point 214. In some embodiments, the dimensions and shape of the portion 215 are the same as the dimensions and shape of the portion 217. In some embodiments, the taper 219 has a same shape (e.g., a same slope) as the taper 221.

FIG. 2C shows a connector 220 having an outward taper 222 (e.g., a widening) in accordance with some embodiments. FIG. 2C further shows relative current densities within the connector 220 when a current is traversing the connector 220 (e.g., based on a current simulation). As shown in FIG. 2C, there is less current density in the wider portion 226 of the connector 220 than in the narrower portion 224 of connector 220.

FIG. 2D shows a connector 230 having an outward taper 232 and a split 234 in accordance with some embodiments. In accordance with some embodiments, the split 234 has an angle of 30 degrees. FIG. 2D further shows a portion 236 having a first width, w₁, a portion 238 having a second width, w₂, and a portion 240 having a third width, w₃. In accordance with some embodiments the first width, w₁, is larger than either of the second width, w₂, or the third width, w₃. FIG. 2D also shows relative current densities within the connector 230 when a current is traversing the connector 230 and a current streamline 231.

The current density lines in FIG. 2D represent a normalized current density topography, ranging from 0 (representing no current) to 1 (representing current density that equals or exceeds a superconducting current density threshold). As shown in FIG. 2D, the portions 236, 238, and 240 have normalized current densities around 0.9 while the tapered region (e.g., the bulge) has normalized current densities between 0.8 and 0.6 and the split 234 has a normalized current density around 0.5.

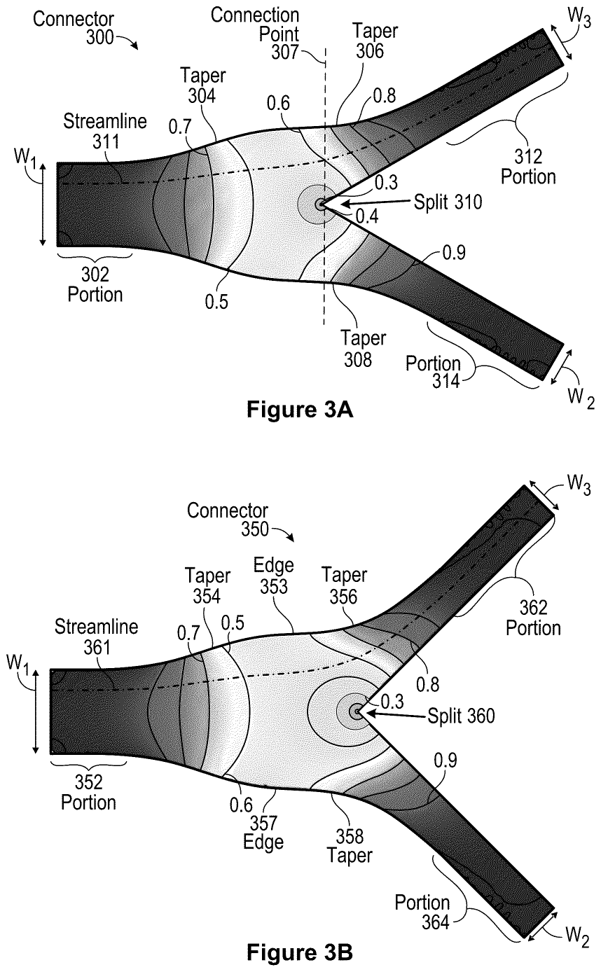

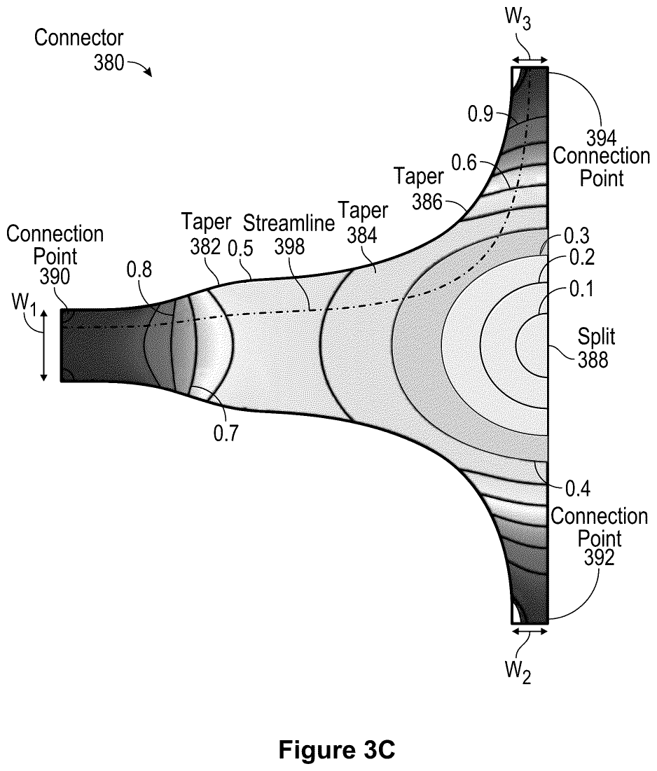

FIGS. 3A-3C are diagrams illustrating example connectors with splits in accordance with some embodiments. FIG. 3A shows a connector 300 having an outward taper 304, a split 310 with corresponding connection point 307, and inward tapers 306 and 308 in accordance with some embodiments. In accordance with some embodiments, the split 310 has an angle of 60 degrees. FIG. 3A further shows a portion 302 having a first width, w₁, a portion 314 having a second width, w₂, and a portion 312 having a third width, w₃. In accordance with some embodiments the first width, w₁, is larger than either of the second width, w₂, or the third width, w₃. FIG. 3A also shows relative current densities within the connector 300 when a current is traversing the connector 300 and a corresponding current streamline 311.

FIG. 3B shows a connector 350 having an outward taper 354 and an inward taper 356 along an edge 353, a split 360, and inward taper 358 along an edge 357 in accordance with some embodiments. In accordance with some embodiments, the split 360 has an angle of 90 degrees. FIG. 3B further shows a portion 352 having a first width, w₁, a portion 364 having a second width, w₂, and a portion 362 having a third width, w₃. In accordance with some embodiments the first width, w₁, is larger than either of the second width, w₂, or the third width, w₃. FIG. 3B also shows relative current densities within the connector 350 when a current is traversing the connector 350 and a corresponding current streamline 361.

FIG. 3C shows a connector 380 having outward tapers 382 and 384, a split 388, and an inward taper 386 in accordance with some embodiments. In accordance with some embodiments, the split 388 has an angle of 180 degrees. FIG. 3C further shows a connection point 390 having a first width, w₁, a connection point 392 having a second width, w₂, and a connection point 394 having a third width, w₃. In accordance with some embodiments the first width, w₁, is larger than either of the second width, w₂, or the third width, w₃. FIG. 3C also shows relative current densities within the connector 380 when a current is traversing the connector 380 and a corresponding current streamline 398.

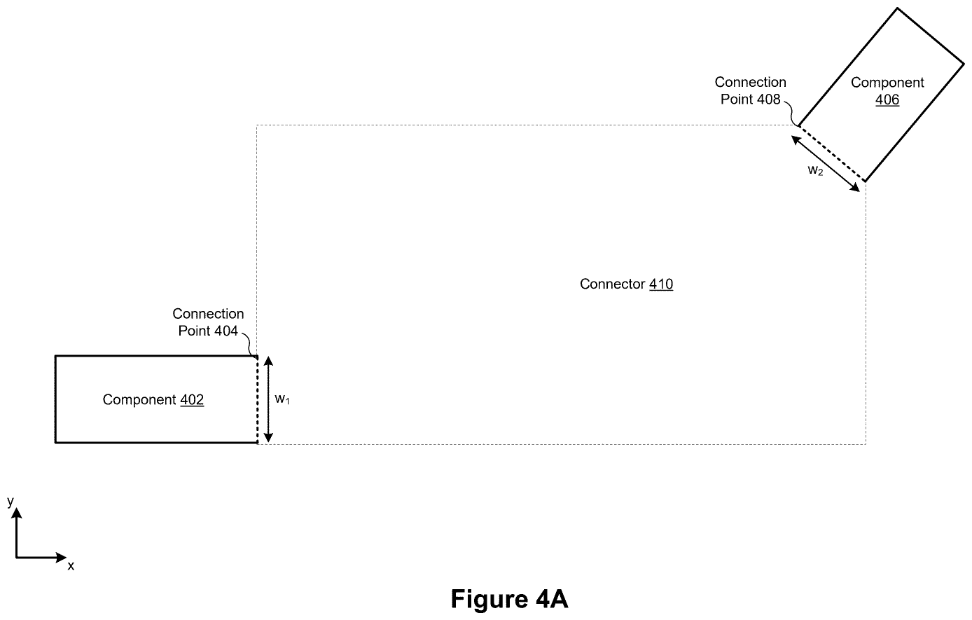

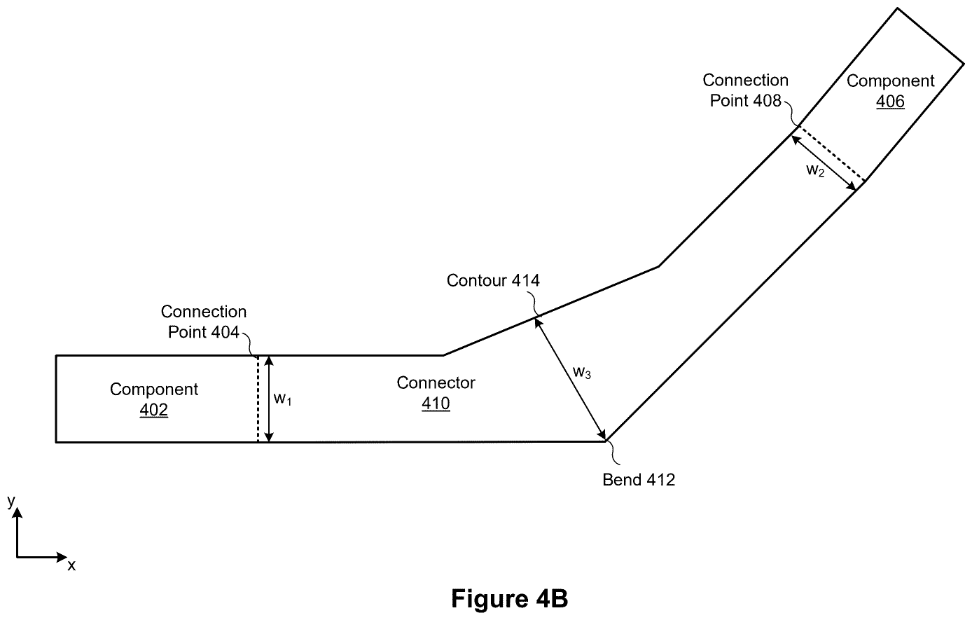

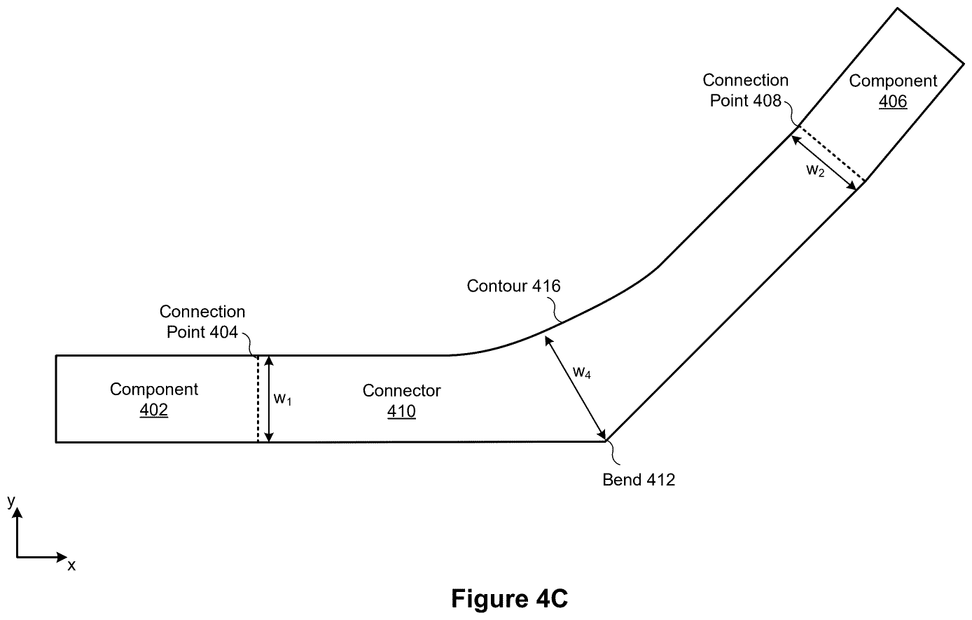

FIGS. 4A-4C are diagrams illustrating an example connector with a bend in accordance with some embodiments. FIG. 4A shows components 402 and 406 coupled by a connector 410 in accordance with some embodiments. The component 402 has a connection point 404 with a first width, w₁, and the component 406 has a connection point 408 with a second width, w₂. In some embodiments, the connection points 404 and 408 have equal widths (w₁ and w₂ are equal). In some embodiments, the connector 410 is adapted (e.g., shaped) to reduce current crowding within the connector. In some embodiments, the components 402 and 406 and the connector 410 are arranged on a same layer of superconducting material (e.g., a superconducting material such as NbGe or NbN). In some embodiments, the connector 410 is formed via etching of a superconducting film. In some embodiments, the components 402, 406 are instances of the component 102 or the component 106.

FIG. 4B shows the connector 410 with a bend 412 (e.g., a turn) and a corresponding edge contour 414 in accordance with some embodiments. As shown in FIG. 4B, the contour 414 has a linear slope increasing in width from the width w₁ at the connection point 404 to a width w₃ at the bend 412 and decreasing in width from the width w₃ at the bend 412 to the width w₂ at the connection point 408.

FIG. 4C shows the connector 410 with the bend 412 and a corresponding edge contour 416 in accordance with some embodiments. As shown in FIG. 4C, the contour 416 has a non-linear slope increasing in width from the width w₁ at the connection point 404 to a width w₄ at the bend 412 and decreasing in width from the width w₄ at the bend 412 to the width w₂ at the connection point 408. In accordance with some embodiments, the width w₄ at the bend 412 in FIG. 4C is less than the width w₃ at the bend 412 in FIG. 2B.

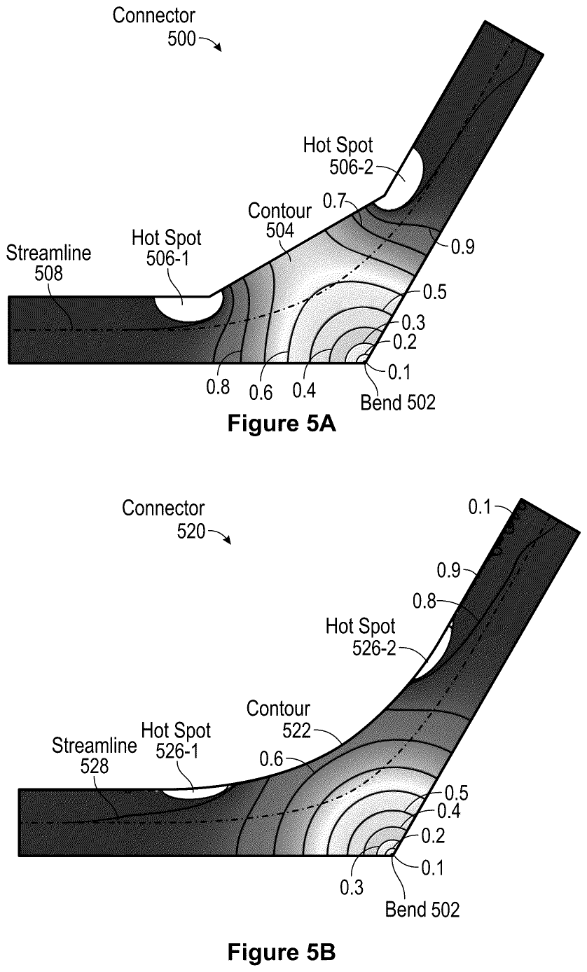

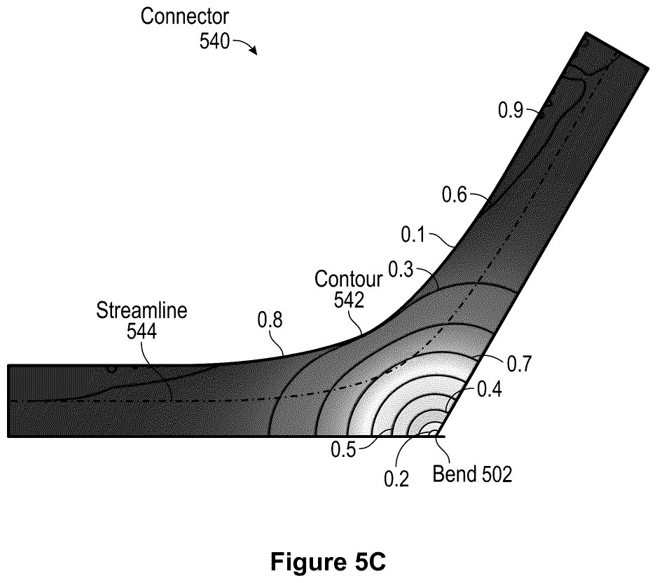

FIGS. 5A-5C are diagrams illustrating example connectors with bends in accordance with some embodiments. FIG. 5A shows the connector 500 with a bend 502 (e.g., a turn) and a corresponding edge contour 504 (e.g., a linear slope contour) in accordance with some embodiments. FIG. 5A further shows relative current densities within the connector 500 when a current is traversing the connector 500 and hot spots 506-1 and 506-2. In accordance with some embodiments, the hot spots 506 are locations where the current density exceeds a superconducting density threshold for the connector 500. FIG. 5A also shows a current streamline 508 adjacent to the hot spots 506.

FIG. 5A shows the connector 500 with a bend 502 (e.g., a turn) and a corresponding edge contour 504 (e.g., a linear slope contour) in accordance with some embodiments. FIG. 5A further shows relative current densities within the connector 500 when a current is traversing the connector 500 and hot spots 506-1 and 506-2. In accordance with some embodiments, the hot spots 506 are locations where the current density exceeds a superconducting density threshold for the connector 500. FIG. 5A also shows a current streamline 508 adjacent to the hot spots 506. As shown in FIG. 5A, the contour 504 results in the hot spots 506 having current densities of 1.0 while the bend 502 has current densities between 0.1 and 0.9.

FIG. 5B shows the connector 520 with the bend 502 and a corresponding edge contour 522 (e.g., a non-linear slope contour) in accordance with some embodiments. In some embodiments, the edge contour 522 in FIG. 5B corresponds to the current streamline 508 in FIG. 5A. FIG. 5B further shows relative current densities within the connector 520, hot spots 526-1 and 526-2, and a current streamline 528 adjacent to the hot spots 526.

FIG. 5C shows the connector 540 with the bend 502 and a corresponding edge contour 542 (e.g., a non-linear slope contour) in accordance with some embodiments. In some embodiments, the edge contour 542 in FIG. 5C corresponds to the current streamline 528 in FIG. 5B. FIG. 5C further shows relative current densities within the connector 540 and a current streamline 544. As shown in FIG. 5C, the contour 542 results in current densities between 0.2 and 0.9 (e.g., no hot spots).

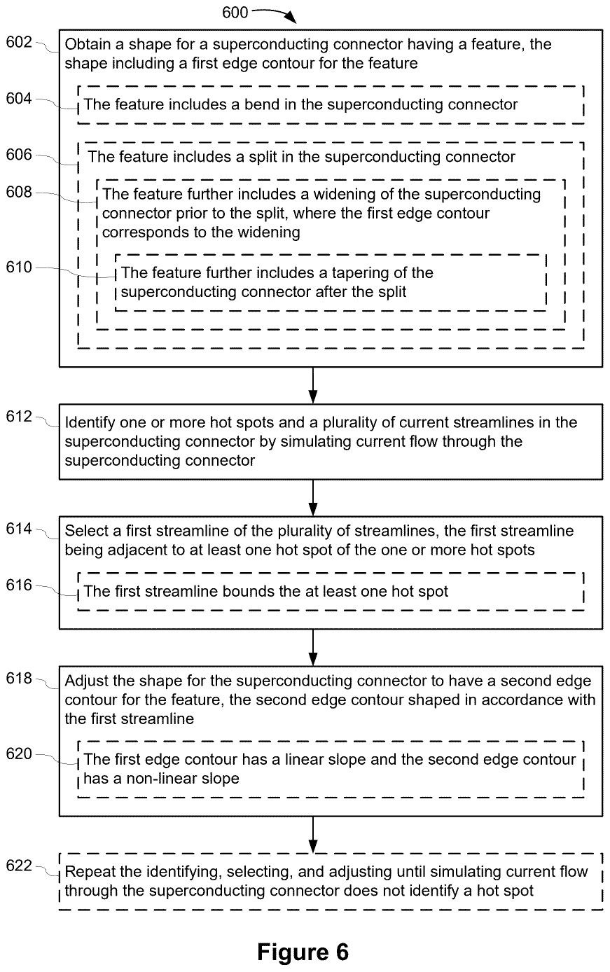

FIG. 6 is a flowchart illustrating a method 600 for generating (e.g., designing) superconducting connectors in accordance with some embodiments. In accordance with some embodiments the method 600 is performed at a computing system having a display, one or more processors, and memory. In some embodiments, the memory stores one or more programs configured for execution by the one or more processors.

The computing system obtains (602) a shape for a superconducting connector having a feature, the shape including a first edge contour for the feature. For example, a user inputs an initial shape for the superconducting connector. In some embodiments, the computing system selects a template shape for the superconducting connector (e.g., a template corresponding to the feature). In some embodiments, the first edge contour has a linear slope (e.g., is composed of one or more straight lines).

In some embodiments, the feature includes (604) a bend in the superconducting connector. For example, the connector 500 in FIG. 5A includes the bend 502. In some embodiments, the bend is a turn having a corresponding turn angle between zero degrees and 180 degrees.

In some embodiments, the feature includes (606) a split in the superconducting connector. In some embodiments, the feature further includes (608) a widening of the superconducting connector prior to the split, where the first edge contour corresponds to the widening. In some embodiments, the feature further includes (610) a tapering of the superconducting connector after the split. For example, the connector 300 in FIG. 3A includes the split 310, the widening taper 304, and the narrowing tapers 306 and 308. As another example, the connector 380 in FIG. 3C includes the split 388, the widening tapers 382 and 384, and the narrowing taper 386.

The computing system identifies (612) one or more hot spots (e.g., the hot spots 506) and a plurality of current streamlines (e.g., the streamline 508) in the superconducting connector by simulating current flow through the superconducting connector. In some embodiments, the one or more hot spots are identified based on a current density topography (e.g., as illustrated in FIG. 5A). In some embodiments, the computing system identifies a hot spot and a current streamline in proximity to the hot spot (e.g., the current streamline bounds the hot spot).

The computing system selects (614) a first streamline (e.g., the streamline 508) of the plurality of streamlines, the first streamline being adjacent to at least one hot spot of the one or more hot spots. In some embodiments, the first streamline bounds (616) the at least one hot spot. In some embodiments, the computing system selects the first streamline in accordance with a determination that the first streamline has a maximum current density below 1.0 (e.g., in the range of (1.0, 0.8]).

The computing system adjusts (618) the shape for the superconducting connector to have a second edge contour for the feature, the second edge contour shaped in accordance with the first streamline. For example, the contour 522 in FIG. 5B corresponds to the streamline 508 in FIG. 5A.

In some embodiments, the first edge contour has (620) a linear slope and the second edge contour has a non-linear slope. For example, the contour 504 in FIG. 5A has a linear slope and the contour 522 in FIG. 5B has a non-linear slope.

In some embodiments, the computing system repeats (622) the identifying, selecting, and adjusting until simulating current flow through the superconducting connector does not identify a hot spot. For example, the contour 542 in FIG. 5C corresponds to the streamline 528 in FIG. 5B and the connector 540 in FIG. 5C does not have any hot spots.

In light of these principles, we now turn to certain embodiments.
(A1) In one aspect, some embodiments include a superconducting circuit (e.g., a circuit configured to operate at a temperature below a critical temperature for superconducting components of the superconducting circuit). The superconducting circuit includes: (i) a first component (e.g., the component 202); (ii) a second component (e.g., the component 208); (iii) a third component (e.g., the component 212); and (iv) a superconducting connector (e.g., the connector 210) electrically connecting the first component, the second component, and the third component, the connector comprising a first section (e.g., the portion 213) that splits at a splitting end (e.g., at the split 211) into a second section (e.g., the portion 215) and a third section (e.g., the portion 217), where: (a) the first section connects to the first component at a first end (e.g., the connection point 204); (b) the first section widens (e.g., the taper 216) prior to the splitting end; and (c) the first section widens in accordance with an electrical current streamline. For example, an external shape of at least one edge of the first section is in accordance with an electrical current streamline of current traversing the first section while the first section is in a superconducting state. As another example, the first section has a greater width at a location between the first end and the splitting end than at the first end. In some embodiments, the width of the first section changes smoothly from the first end to the splitting end. In some embodiments, the electrical current streamline is determined by simulating the current through the superconducting circuit, and is based on the shape of superconducting circuit.
(A2) In some embodiments of A1, the second section (e.g., the portion 215) tapers from a first width at the split. For example, FIG. 2B shows the taper 219 from the split 211, with width w₄/2, to the connection point 206, with width w₂.
(A3) In some embodiments of A2, the second section tapers in accordance with an electrical current streamline (e.g., for current traversing the second section).
(A4) In some embodiments of A2 or A3, the taper has a non-linear slope. For example, the taper 219 in FIG. 2B has a non-linear slope (e.g., that corresponds to a current streamline).
(A5) In some embodiments of any of A2-A4, a slope of the taper of the second section matches a slope of the widening of the first section at a connection point between the first section and the second section (e.g., the external shape of the connector has continuous first derivative). For example, the slope of the taper 304 in FIG. 3A matches the slope of the taper 306 at the connection point 307 corresponding to the split 310.
(A6) In some embodiments of A5, an edge of the superconducting connector has a continuous first derivative over the length of the edge of the superconducting connector. In some embodiments, each outer edge of the connector has a continuous first derivative. For example, the edges 353 and 357 of the connector 350 each have a continuous first derivative in FIG. 3B.
(A7) In some embodiments of any of A1-A6, the first section has a maximum width at the splitting end. For example, the connector 210 in FIG. 2B has a maximum width w₄/2 at the split 211. In some embodiments, a maximum width of the first section is located between the first end and the splitting end (e.g., the connector has a bulge between the first end and the splitting end).
(A8) In some embodiments of any of A1-A7, the first section widens with a non-linear slope. For example, FIG. 2B shows the portion 213 with the non-linear taper 216. In some embodiments, the first section widens in accordance with Equations (3)-(7) above.
(A9) In some embodiments of any of A1-A8, the first section widens to reduce current crowding at the splitting end (e.g., to reduce current density in a portion of the first section that includes the splitting end). For example, to prevent hot spots from forming as illustrated by the current densities in FIGS. 3A-3C.
(A10) In some embodiments of any of A1-A9, at least one of the first component, the second component, and the third component is a superconducting component. For example, one of the components is a superconducting photon detector, a superconducting switch (e.g., transistor), or a superconducting logic gate (e.g., a logical AND or gate).
(A11) In some embodiments of any of A1-A10, at least one of the first component, the second component, and the third component is a via or contact pad. In some embodiments, a current source is electrically-coupled to the via or contact pad such that current flows from the via or contact pad through connector. In some embodiments, a readout component is electrically-coupled to the via or contact pad and configured to determine a state of connector or the other components (e.g., the first, second, or third component). For example, the readout component determines the state based on an amount of current received at the readout component. In some embodiments, at least one of the components is a conducting or semiconducting component. In some embodiments, at least one of the components is, or includes, a transistor, an inductor, a resistor, or a capacitor.

Many modifications and variations of this disclosure can be made without departing from its spirit and scope, as will be apparent to those skilled in the art. The specific embodiments described herein are offered by way of example only, and the disclosure is to be limited only by the terms of the appended claims, along with the full scope of equivalents to which such claims are entitled.

It will also be understood that, although the terms first, second, etc. are, in some instances, used herein to describe various elements, these elements should not be limited by these terms. These terms are only used to distinguish one element from another. For example, a first current could be termed a second current, and, similarly, a second current could be termed a first current, without departing from the scope of the various described embodiments. The first current and the second current are both currents, but they are not the same current unless explicitly stated as such.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, a “superconducting circuit” or “superconductor circuit” is a circuit having one or more superconducting materials. For example, a superconductor switch circuit is a switch circuit that includes one or more superconducting materials. As used herein, a “superconducting” material is a material that is capable of operating in a superconducting state (under particular conditions). For example, a superconducting material is a material that operates as a superconductor (e.g., operates with zero electrical resistance) when cooled below a particular temperature (e.g., a threshold temperature) and having less than a threshold current flowing through it. A superconducting material is also sometimes called a superconduction-capable material. In some embodiments, the superconducting materials operate in an “off” state where little or no current is present. In some embodiments, the superconducting materials can operate in a non-superconducting state during which the materials have a non-zero electrical resistance (e.g., a resistance in the range of one thousand to ten thousand ohms). For example, a superconducting material supplied with a current greater than a threshold superconducting current for the superconducting material transitions from a superconducting state having zero electrical resistance to a non-superconducting state having non-zero electrical resistance.

As used herein, a “connector” is a section of material configured for transferring electrical current. In some embodiments, a connector includes a section of material conditionally capable of transferring electrical current. For example, a connector made of a superconducting material that is capable of transferring electrical current while the connector is maintained at a temperature below a threshold temperature. A cross-section of a connector (e.g., a cross-section that is perpendicular to a length of the connector) optionally has a regular (e.g., flat or round) shape or an irregular shape. While some of the figures show connector having rectangular shapes, any shape could be used. In some embodiments, a length of a connector is greater than a width or a thickness of the connector (e.g., the length of a connector is at least 5, 6, 7, 8, 9, or 10 times greater than the width and the thickness of the connector). In some embodiments, a connector is a section of a superconducting layer.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A superconducting circuit, comprising:
a first component;
a second component;
a third component; and
a superconducting connector electrically connecting the first component, the second component, and the third component, the connector comprising a first section that splits at a splitting end into a second section and a third section;
wherein the first section connects to the first component at a first end;
wherein the first section widens prior to the splitting end; and
wherein the first section widens in accordance with an electrical current streamline.

2. The superconducting circuit of claim 1, wherein the second section tapers from a first width at the split end.

3. The superconducting circuit of claim 2, wherein the second section tapers in accordance with an electrical current streamline.

4. The superconducting circuit of claim 2, wherein the taper has a non-linear slope.

5. The superconducting circuit of claim 2, wherein a slope of the taper of the second section matches a slope of the widening of the first section at a connection point between the first section and the second section.

6. The superconducting circuit of claim 5, wherein an edge of the superconducting connector has a continuous first derivative over the length of the edge of the superconducting connector.

7. The superconducting circuit of claim 1, wherein the first section has a maximum width at the splitting end.

8. The superconducting circuit of claim 1, wherein the first section widens with a non-linear slope.

9. The superconducting circuit of claim 1, wherein the first section widens to reduce current crowding at the splitting end.

10. The superconducting circuit of claim 1, wherein at least one of the first component, the second component, and the third component comprises a superconducting component.

11. The superconducting circuit of claim 1, wherein at least one of the first component, the second component, and the third component comprises a via or contact pad.

12. A method of generating superconducting connectors, the method comprising:
setting a shape for a superconducting connector having a feature, the shape including a first edge contour for the feature;
identifying one or more hot spots and a plurality of current streamlines in the superconducting connector by simulating current flow through the superconducting connector;
selecting a first streamline of the plurality of current streamlines, the first streamline being adjacent to at least one hot spot of the one or more hot spots; and
adjusting the shape for the superconducting connector to have a second edge contour for the feature, the second edge contour shaped in accordance with the first streamline.

13. The method of claim 12, wherein the first streamline bounds the at least one hot spot.

14. The method of claim 12, further comprising repeating the identifying, selecting, and adjusting until simulating current flow through the superconducting connector does not identify a hot spot.

15. The method of claim 12, wherein the feature comprises a bend in the superconducting connector.

16. The method of claim 12, wherein the feature comprises a split in the superconducting connector.

17. The method of claim 16, wherein the feature further comprises a widening of the superconducting connector prior to the split, wherein the first edge contour corresponds to the widening.

18. The method of claim 17, wherein the feature further comprises a tapering of the superconducting connector after the split.

19. The method of claim 12, wherein the first edge contour has a linear slope and the second edge contour has a non-linear slope.
